(19) United States
(12) Patent Application Publication
(10) Pub. No.: US 2013/0075831 A1
(43) Pub. Date: Mar. 28, 2013

(54) METAL GATE STACK HAVING TIALN BLOCKING/WETTING LAYER

(71) Applicants: Shiu-Ko JangJian, Tainan City (TW); Szu-An Wu, Tainan City (TW); Ying-Lang Wang, Tai-Chung County (TW); Chi-Wen Liu, HsinChu (TW)

(72) Inventors: Shiu-Ko JangJian, Tainan City (TW); Szu-An Wu, Tainan City (TW); Ying-Lang Wang, Tai-Chung County (TW); Chi-Wen Liu, HsinChu (TW)

(73) Assignee: TAIWAN SEMICONDUCTOR MANUFACTURING COMPANY, LTD., Hsin-Chu (TW)

(21) Appl. No.: 13/244,355

(22) Filed: Sep. 24, 2011

(51) Int. Cl. H01L 29/78; H01L 21/336

(52) U.S. Cl. 257/410; 438/287; 257/E29.255; 257/E21.409

(57) ABSTRACT

A metal gate stack having a TiAlN blocking/wetting layer, and methods of manufacturing the same, are disclosed. In an example, an integrated circuit device includes a semiconductor substrate and a gate stack disposed over the semiconductor substrate. The gate stack includes a gate dielectric layer disposed over the semiconductor substrate; a work function layer disposed over the gate dielectric layer; a multi-function wetting/blocking layer disposed over the work function layer, wherein the multi-function wetting/blocking layer is a titanium aluminum nitride layer; and a conductive layer disposed over the multi-function wetting/blocking layer.

### BACKGROUND

The semiconductor integrated circuit (IC) industry has experienced rapid growth. Technological advances in IC materials and design have produced generations of ICs where each generation has smaller and more complex circuits than the previous generation. These advances have increased the complexity of processing and manufacturing ICs and, for these advances to be realized, similar developments in IC processing and manufacturing are needed. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs and, for these advances to be realized, similar developments in IC processing and manufacturing are needed.

### BRIEF DESCRIPTION OF THE DRAWINGS

The present disclosure is best understood from the following detailed description when read with the accompanying figures. It is emphasized that, in accordance with the standard practice in the industry, various features are not drawn to scale and are used for only illustration purposes. In fact, the dimensions of the various features may be arbitrarily increased or reduced for clarity of discussion.

FIG. 1 is a flow chart of a method for fabricating an integrated circuit device according to various aspects of the present disclosure.

FIGS. 2-7 are diagrammatic cross-sectional views of an integrated circuit device during various stages of the method of FIG. 1 according to various aspects of the present disclosure.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

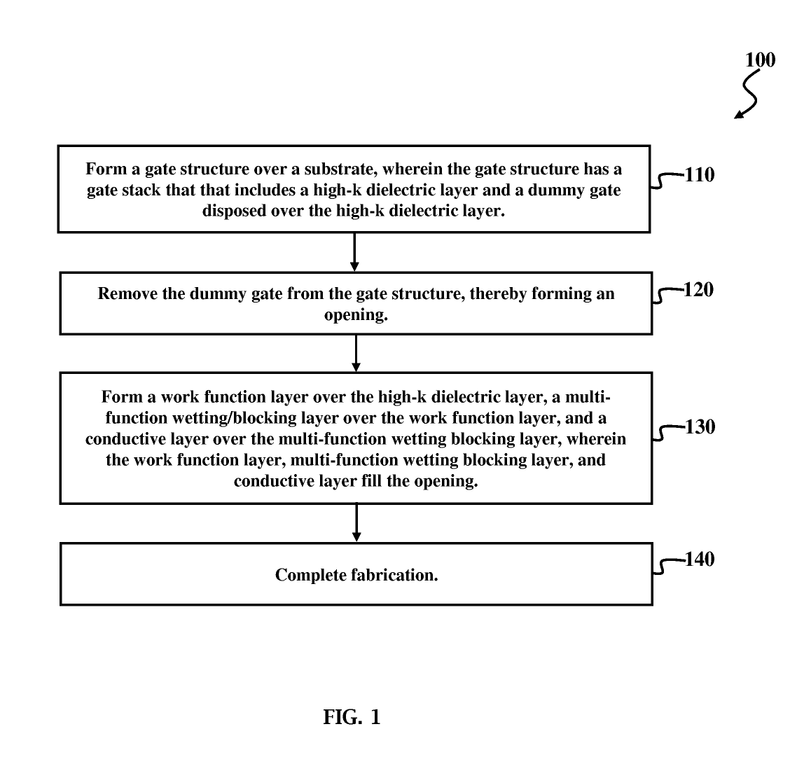

FIG. 1 is a flow chart of a method 100 for fabricating an integrated circuit device, in portion or entirety, according to various aspects of the present disclosure. The method 100 begins at block 110 where a gate structure is formed over a substrate. The gate structure has a gate stack that includes a high-k dielectric layer disposed over the substrate and a dummy gate disposed over the high-k dielectric layer. At block 120, the dummy gate is removed from the gate structure to form an opening therein. At block 130, a work function layer, a multi-function wetting/blocking layer, and a conductive layer are formed to fill the opening. The work function layer is formed over the high-k dielectric layer, the multi-function wetting/blocking layer is formed over the work function layer, and the conductive layer is formed over the multi-function wetting/blocking layer. The multi-function wetting/blocking layer includes a material that sufficiently prevents (or reduces) metal impurities from penetrating the high-k dielectric layer (for example, from the conductive layer) during processing, while providing sufficient wettability (in other words, desired interface quality) with the conductive layer. The method 100 may continue at block 140 to complete fabrication of the integrated circuit device. Additional steps can be provided before, during, and after the method 100, and some of the steps described can be replaced or eliminated for additional embodiments of the method 100.

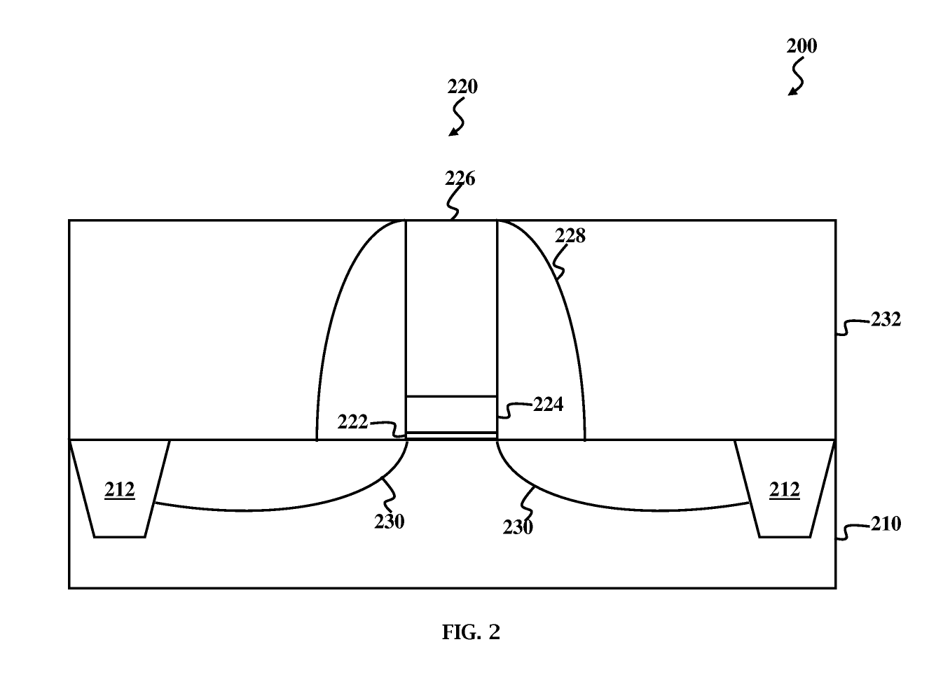

FIGS. 2-7 are diagrammatic cross-sectional views of an integrated circuit device 200, in portion or entirety, at various stages of fabrication according to the method 100 of FIG. 1. FIGS. 2-7 have been simplified for the sake of clarity to better understand the inventive concepts of the present disclosure. In the depicted embodiment, the integrated circuit device 200 includes a field-effect transistor device, such as an n-channel field effect transistor (NFET) or a p-channel field effect transistor (PFET). The integrated circuit device 200 may be included in memory cells and/or logic circuits that include passive components such as resistors, capacitors, inductors, and/or fuses; active components, such as metal-oxide-semiconductor field effect transistors (MOSFETs), complementary metal-oxide-semiconductor transistors (CMOSs), high voltage transistors, and/or high frequency transistors; other suitable components; or combinations thereof. Additional features can be added in the integrated circuit device 200, and some of the features described below can be replaced or eliminated in other embodiments of the integrated circuit device 200.

In FIG. 2, the integrated circuit device 200 includes a substrate 210. In the depicted embodiment, the substrate 210 is a semiconductor substrate including silicon. Alternatively or additionally, the substrate 210 includes another elementary semiconductor, such as germanium; a compound semiconductor including silicon carbide, gallium arsenic, gallium phosphide, indium phosphide, indium arsenide, and/or indium antimonide; an alloy semiconductor including SiGe, GaAsP, AlinAs, AlGaAs, GaInAs, GaInP, and/or GaInAsP; or combinations thereof. In yet another alternative, the substrate 210 is a semiconductor on insulator (SOI). In other alternatives, semiconductor substrate 210 may include a doped epi layer, a gradient semiconductor layer, and/or a semiconductor layer overlying another semiconductor layer of a different type, such as a silicon layer on a silicon germanium layer. The substrate 210 includes various doping configurations depending on design requirements of the integrated circuit device 200. For example, the substrate 210 may include various doped regions doped with p-type dopants, such as boron or BF₂; n-type dopants, such as phosphorus or arsenic; or combinations thereof. The doped regions may be formed on the semiconductor substrate, in a P-well structure, in a N-well structure, in a dual-well structure, or using a raised structure.

An isolation feature 212 is disposed in the substrate 210 to isolate various regions and/or devices of the substrate 210. The isolation feature 212 utilizes isolation technology, such as local oxidation of silicon (LOCOS) and/or shallow trench isolation (STI), to define and electrically isolate the various regions. The isolation feature 212 includes silicon oxide, silicon nitride, silicon oxynitride, other suitable materials, or combinations thereof. The isolation feature 212 is formed by any suitable process. As one example, forming an STI includes using a lithography process to expose a portion of the substrate, etching a trench in the exposed portion of the substrate (for example, by using a dry etching and/or wet etching), and filling the trench (for example, by using a chemical vapor deposition process) with one or more dielectric materials. For example, the filled trench may have a multi-layer structure, such as a thermal oxide liner layer filled with silicon nitride or silicon oxide.

A gate structure 220 is disposed over the substrate 210. In the depicted embodiment, the gate structure 220 includes a gate stack having an interfacial dielectric layer 222, a high-k dielectric layer 224, and a dummy gate layer 226. The interfacial dielectric layer 222 and the high-k dielectric layer 224 may collectively be referred to as a gate dielectric layer of the gate structure 220. The gate stack may include additional layers, such as a hard mask layer, a capping layer, a diffusion/barrier layer, a dielectric layer, a metal layer, other suitable layers, or combinations thereof. The gate structure 220 is formed by a process that includes deposition processes, lithography patterning processes, etching processes, other suitable processes, or combinations thereof. The deposition processes include physical vapor deposition (PVD), chemical vapor deposition (CVD), atomic layer deposition (ALD), plasma enhanced CVD (PECVD), remote plasma CVD (RPCVD), molecular organic CVD (MOCVD), sputtering, plating, other suitable methods, or combinations thereof. The lithography patterning processes include resist coating (for example, spin-on coating), soft baking, mask aligning, exposure, post-exposure baking, developing the photoresist, rinsing, drying (for example, hard baking), other suitable processes, or combinations thereof. The lithography exposure process may be implemented or replaced by other proper methods such as maskless lithography, electron-beam writing, ion-beam writing, and molecular imprint. The etching processes include dry etching, wet etching, or combinations thereof.

The interfacial dielectric layer 222 is disposed over the substrate 210. In an example, the interfacial dielectric layer 222 has a thickness of about 5 Å to about 20 Å. In the depicted embodiment, the interfacial dielectric layer 222 is an oxide-containing layer, such as a silicon oxide (SiO₂) layer or a silicon oxynitride (SiON) layer. The interfacial layer 222 may include other suitable materials. The interfacial dielectric layer 222 is formed by a chemical oxide technique, thermal oxide technique, atomic layer deposition (ALD), chemical vapor deposition (CVD), or other suitable technique. A cleaning process, such as an HF-last pre-gate cleaning process (for example, using a hydrofluoric (HF) acid solution), may be performed before the interfacial dielectric layer 222 is formed over the substrate 210.

The high-k dielectric layer 224 is disposed over the interfacial dielectric layer 222, and the dummy gate layer 226 is disposed over the high-k dielectric layer 224. A thickness of the high-k dielectric layer 224 and the dummy gate layer 226 depends on design requirements of the integrated circuit device 200. In an example, the high-k dielectric layer 224 has a thickness of about 5 Å to about 30 Å, and the dummy gate layer has a thickness of about 350 Å to about 700 Å. The high-k dielectric layer 224 includes a high-k dielectric material, such as HfO₂, HfSiO, HfSiON, HfTaO, HfTiO, HfZrO, zirconium oxide, aluminum oxide, hafnium dioxide-alumina (HfO₂—Al₂O₃) alloy, other suitable high-k dielectric materials, or combinations thereof. The dummy gate layer 226 includes a material suitable for a gate replacement process. For example, in the depicted embodiment, the dummy gate layer 226 include polysilicon.

The gate structure 220 further includes spacers 228 formed by a suitable process. For example, a dielectric layer, such as a silicon nitride layer, is blanket deposited over the integrated circuit device 200; and then, the silicon nitride layer is anisotropically etched to remove the silicon nitride layer to form spacers 228 as illustrated in FIG. 2. The spacers 228 are positioned adjacent sidewalls of the gate stack (interfacial dielectric layer 222, high-k dielectric layer 224, and dummy gate layer 226) of the gate structure 220. Alternatively or additionally, the spacers 228 include another dielectric material, such as silicon oxide, silicon carbon nitride, or combinations thereof.

Various source/drain features 230 may be disposed in the substrate 210. The source/drain features 230 are interposed by the gate structure 220. The source/drain features 230 may include lightly doped source and drain (LDD) regions and/or heavily doped source and drain (HDD) regions. The LDD and/or HDD regions may be formed by ion implantation or diffusion of n-type dopants, such as phosphorous or arsenic, or p-type dopants, such as boron or BF₂. An annealing process, such as a rapid thermal annealing and/or a laser thermal annealing, may be performed to activate dopants of the LDD and/or HDD regions. The LDD and/or HDD regions may be formed at any time in the depicted embodiment. The source/drain features 230 may include raised source/drain features, such as epitaxial features (for example, silicon germanium epitaxial features or silicon epitaxial features). Silicide features may be disposed over the source/drain features 230, for example, to reduce contact resistance. The silicide features may be formed over the source and drain features by a self-aligned salicide process, which can include depositing a metal layer, annealing the metal layer such that the metal layer is able to react with silicon to form silicide, and then removing the non-reacted metal layer.

A dielectric layer 232 is disposed over the substrate 210, such as an interlayer (or inter-level) dielectric (ILD) layer. The dielectric layer 232 includes a dielectric material, such as silicon oxide, silicon nitride, silicon oxynitride, tetraethylorthosilicate (TEOS) formed oxide, phosphosilicate glass (PSG), borophosphosilicate glass (BPSG), low-k dielectric material, other suitable dielectric material, or combinations thereof. Exemplary low-k dielectric materials include fluorinated silica glass (FSG), carbon doped silicon oxide, Black Diamond® (Applied Materials of Santa Clara, Calif.), Xerogel, Aerogel, amorphous fluorinated carbon, Parylene, BCB (bis-benzocyclobutenes), SiLK (Dow Chemical, Midland, Michigan), polyimide, other proper materials, and/or combinations thereof. The dielectric layer 232 may include a multilayer structure including multiple dielectric materials. The dielectric layer 232 is formed by a suitable process to a suitable thickness, including by CVD, high density plasma CVD, spin-on, and/or other suitable methods. Subsequent to the deposition of the dielectric layer 232, a chemical mechanical polishing (CMP) process is performed until a top portion of the gate structure 220 is reached/exposed. Particularly, a top portion of the gate stack of the gate structure 220 (here, the dummy gate layer 226) is exposed as illustrated in FIG. 2. Additional layers may be formed overlying and/or underlying the dielectric layer 232.

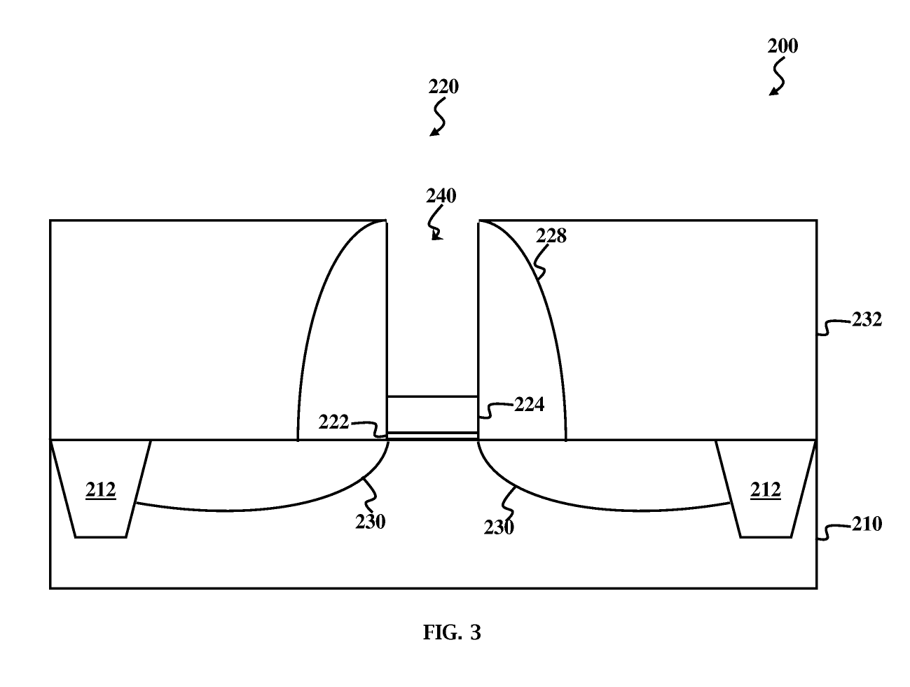

In FIGS. 3-7, a gate replacement process is performed, where the dummy gate layer 226 is replaced with a metal gate. In FIG. 3, the dummy gate layer 226 is removed from the gate stack of the gate structure 220, thereby forming an opening 240. The opening 240 exposes the high-k gate dielectric layer 224. The dummy gate layer 226 may be removed by an etching process, other suitable process, or combinations thereof. In an example, an etching process selectively etches the dummy gate layer 226.

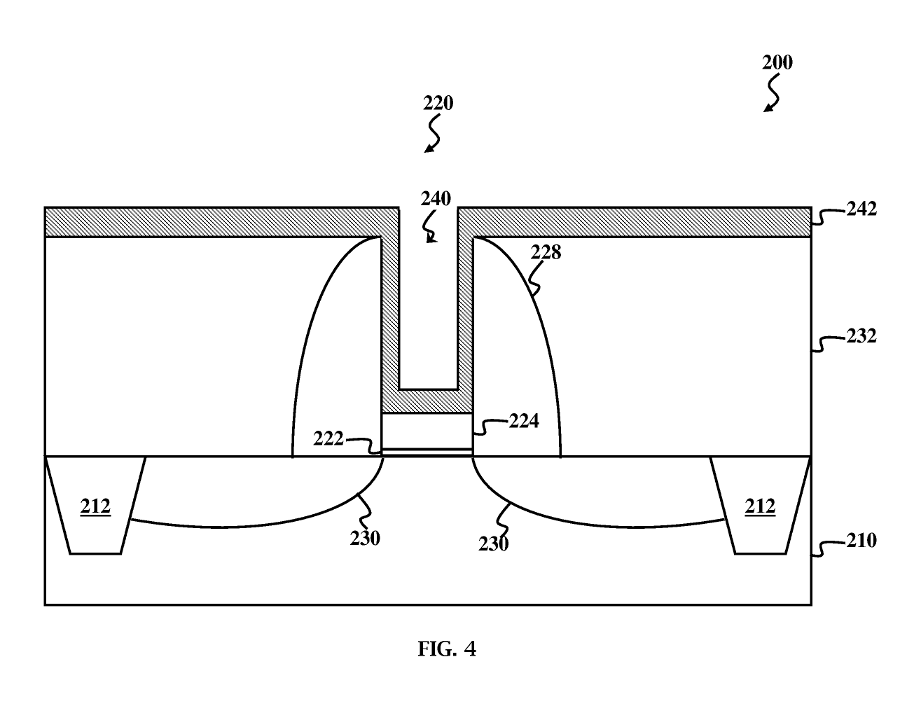

In FIG. 4, a work function layer 242 is formed over the substrate 210, such that the work function layer 242 partially fills the opening 240. The work function layer 242 is disposed along sidewalls of the gate structure 220 that define the opening 240. In the depicted embodiment, the work function layer 242 is disposed over the high-k dielectric layer 224. In an example, the work function layer 242 has a thickness of about 30 Å to about 100 Å. In an example, the work function layer 242 disposed on the high-k dielectric layer has a thickness of about 30 Å to about 100 Å, and the work function layer 242 disposed along sidewalls of the opening 240 may have a thickness less than 30 Å, or a thickness of about 30 Å to about 100 Å. The work function layer 242 includes a material that can be tuned to have a proper work function for enhanced performance of the associated device. For example, if a p-type field-effect transistor (PFET) device, the work function layer 242 includes a p-type work function material that can be configured to have a desired work function value for the gate electrode of the PFET. On the other hand, if an n-type field-effect transistor (NFET) device, the work function layer 242 includes an n-type work function material that can be configured to have a desired work function value of the gate electrode of the NFET. The work function layer 242 is formed by a physical vapor deposition (PVD), chemical vapor deposition (CVD), atomic layer deposition (ALD), plasma enhanced CVD (PECVD), remote plasma CVD (RPCVD), molecular organic CVD (MOCVD), sputtering, plating, other suitable method, or combinations thereof.

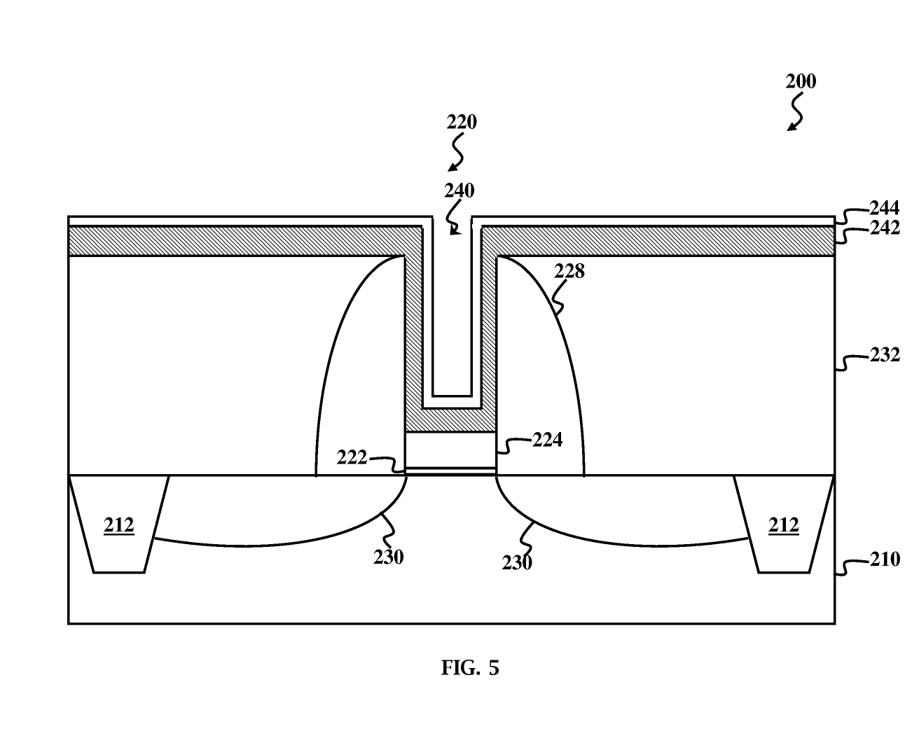

In FIG. 5, a multi-function wetting/blocking layer 244 is formed over the substrate 210, such that the multi-function wetting/blocking layer 244 layer partially fills the opening 240. The multi-function wetting/blocking layer 244 is disposed over the work function layer 244. In an example, the multi-function wetting/blocking layer 244 has a thickness of about 30 Å to about 100 Å. The multi-function wetting/blocking layer 244 functions as both a blocking (or barrier) layer and a wetting layer during processing. For example, the multi-function wetting/blocking layer 244 prevents or reduces metal impurities from penetrating any dielectric layers disposed below the multi-function wetting/blocking layer 244 (such as the gate dielectric of the gate stack of the gate structure 220) while providing desirable interface quality between the multi-function wetting/blocking layer 244 and any material layer formed over the multi-function wetting/blocking layer 244. Accordingly, in the depicted embodiment, the multi-function wetting/blocking layer 244 prevents or reduces metal impurities from penetrating into the high-k dielectric layer 224 and the interfacial dielectric layer 222, while providing optimal interface quality between a layer of the gate stack of the gate structure 220 that is formed over the multi-function wetting/blocking layer 244 (such as a conductive layer 246). Such functionality is described in further detail below.

In the depicted embodiment, the multi-function wetting/blocking layer 244 includes titanium aluminum nitride (TiAlN). An atomic concentration of nitrogen of the TiAlN layer is optimized, such that the multi-function wetting/blocking layer 244 adequately prevents or reduces metal impurities from penetrating underlying dielectric layers (for example, high-k dielectric layer 224 and interfacial layer 222) while minimally effecting a work function of the integrated circuit device 200. For example, it has been observed that nitrogen atomic concentrations less than 10% cannot provide the desired “blocking” capability to metal impurities, whereas nitrogen atomic concentrations greater than 50% can effect (or contribute to) the work function of the integrated circuit device 200. Accordingly, in the depicted embodiment, the TiAlN layer includes a nitrogen atomic concentration of about 10% to about 50%. In the depicted embodiment, the TiAlN ratio further includes a Ti:Al ratio that enhances interface quality (which can be referred to as wettability) between the multi-function wetting/blocking layer 244 and an overlying layer that includes aluminum). For example, the TiAlN layer includes a Ti:Al ratio of about 1:1 to about 1:3.

The process used to form the multi-function wetting/blocking layer 244, here, the TiAlN layer, is tuned to achieve optimal blocking and wettability functionality of the multi-function wetting/blocking layer 244. In the depicted embodiment, a physical vapor deposition (PVD) is used to form the TiAlN layer. Various process parameters of the PVD process, such as substrate temperature, gas type, gas flow rate, chamber pressure, DC power, bias power, process time, other suitable parameters, or combinations thereof, are tuned to achieve the desired blocking and wettability functionality. Alternatively, the multi-function wetting/blocking layer 244 is formed by other processes, such as chemical vapor deposition (CVD), atomic layer deposition (ALD), plasma enhanced CVD (PECVD), remote plasma CVD (RPCVD), molecular organic CVD (MOCVD), sputtering, plating, other suitable method, or combinations thereof. Various process parameters of such alternative processes may be tuned to achieve the desired blocking and wettability functionality of the multi-function wetting/blocking layer 244.

In the depicted embodiment, a high pressure PVD process, which maintains the chamber pressure of about 20 mTorr to about 40 mTorr, deposits the multi-function wetting/blocking layer 244. The high pressure PVD process can ensure that the multi-function wetting/blocking layer 244 adequately, partially fills the opening 240. For example, it has been observed that a chamber pressure less than 20 mTorr can lead to the multi-function wetting/blocking layer 244 inadequately covering the work function layer 242 within the opening 240, and a chamber pressure greater than 40 mTorr can lead to the multi-function wetting/blocking layer 244 undesirably overhanging at a top portion of the opening 240, such that the multi-function wetting blocking layer 244 merges at the top portion of the opening 240 to form a gap therein. The high pressure PVD process thus provides adequate coverage, for example, for high aspect ratio openings, such as the opening 240. For example, in the depicted embodiment, high aspect ratio openings refer to openings having a height to width ratio greater than or equal to 2.2 (height/width≧2.2). Alternatively, high aspect ratio openings may be defined by other height to width ratios.

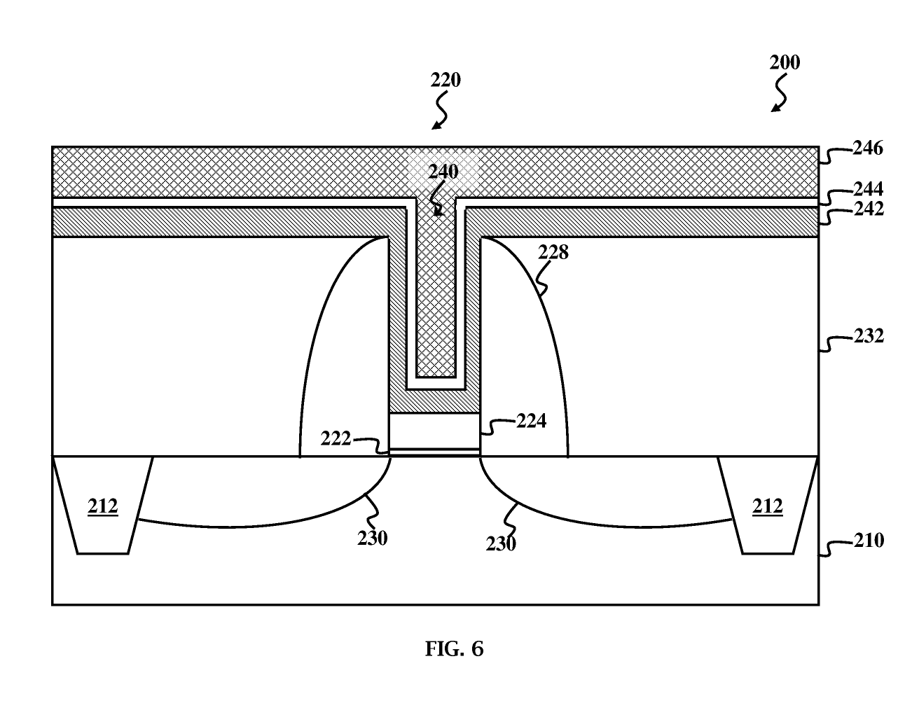

In FIG. 6, a conductive layer 246 is formed over the substrate 210, such that the conductive layer 246 partially fills the opening 240. The conductive layer 246 is disposed over the multi-function wetting/blocking layer 244. In an example, the conductive layer 246 has a thickness of about 300 Å to about 1,500 Å. In the depicted embodiment, the conductive layer 246 includes aluminum. Alternatively or additionally, the conductive layer 246 includes copper, tungsten, a metal alloy, a metal silicide, other conductive material, or combinations thereof. The work function layer 242 is formed by a physical vapor deposition (PVD), chemical vapor deposition (CVD), atomic layer deposition (ALD), plasma enhanced CVD (PECVD), remote plasma CVD (RPCVD), molecular organic CVD (MOCVD), sputtering, plating, other suitable method, or combinations thereof.

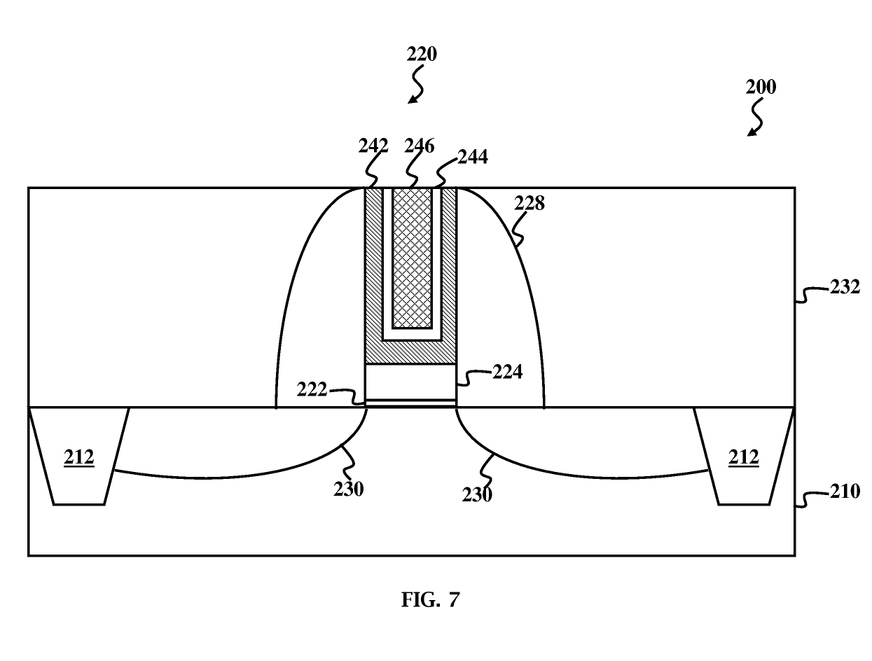

In FIG. 7, a chemical mechanical polishing (CMP) process is performed until the dielectric layer 232 is reached or exposed. The CMP process thus removes portions of the work function layer 242, multi-function wetting/blocking layer 244, and the conductive layer 246 that are disposed over the dielectric layer 232. The remaining portions of the work function layer 242, multi-function wetting/blocking layer 244, and the conductive layer 246 combine to fill the opening 240, such that the gate stack of the gate structure 220 includes the interfacial dielectric layer 222, the high-k dielectric layer 224, the work function layer 242, multi-function wetting/blocking layer 244, and the conductive layer 246. The work function layer 242, the multi-function wetting/blocking layer 244, and the conductive layer 246 may collectively be referred to as a gate electrode of the gate structure 220.

The integrated circuit device 200 may include other features. For example, a multilayer interconnection (MLI) including metal layers and inter-metal dielectric (IMD) layers may be formed over the substrate 210, such as over the dielectric layer 232, to electrically connect various features or structures of the integrated circuit device 200. The multilayer interconnection includes vertical interconnects, such as vias or contacts, and horizontal interconnects, such as metal lines. In an example, the MLI includes interconnection features to the source/drain features 230 and/or the gate stack of the gate structure 220. The various interconnection features include various conductive materials including aluminum, copper, titanium, tungsten, alloys thereof, silicide materials, other suitable materials, or combinations thereof. In an example, a damascene process or dual damascene process is used to form a copper or aluminum multilayer interconnection structure.

The integrated circuit device 200 exhibits reduced leakage current, leading to improved device performance. Such reduced leakage current and improved device performance may be achieved by the multi-function wetting/blocking layer 244 in the gate stack of the gate structure 220. The multi-function wetting/blocking layer 244 can sufficiently block metal impurities from penetrating underlying dielectric layers while providing sufficient wettability (interface quality) to overlying layers. The multi-function wetting/blocking layer 244 can thus replace separate wetting and blocking layers implemented in conventional integrated circuit devices. For example, a conventional gate stack includes a gate dielectric layer, a work function layer disposed over the gate dielectric layer; a blocking layer, such as a tantalum nitride (TaN) blocking layer, disposed over the work function layer; a wetting layer, such as a titanium (Ti) wetting layer, disposed over the blocking layer; and a conductive layer, such as an aluminum (Al) conductive layer, disposed over the wetting layer. The TaN blocking layer provides less than desirable blocking capability, and it has been observed that aluminum impurities from the aluminum conductive layer, can penetrate the gate dielectric layer during processing. Further, though the Ti wetting layer provides sufficient wettability to the Al conductive layer, it has been observed that phase transformations occur between the Ti wetting layer and the Al conductive layer during processing, leading to portions of the TaN blocking layer interacting with Ti during processing, and eventually leading to missing portions of the TaN blocking layer (in other words, portions of the TaN blocking layer are consumed during processing). The missing portions of the TaN blocking layer further minimizes the TaN blocking layer's ability to prevent the aluminum impurities from penetrating the gate dielectric layer. Such phase transformations and missing portions of TaN blocking layer have also been observed when the gate stack includes a titanium aluminum (TiAl) wetting layer. To address such issues, the present disclosure replaces the separate TaN blocking layer and Ti wetting layer of conventional gate stacks with the multi-function wetting/blocking layer 244, such as the TiAlN multi-function wetting/blocking layer. The blocking ability of TiAlN exceeds the blocking ability of TiN and TaN (specifically, blocking ability of TiAlN>TiN>>TaN). Further, TiAlN provides sufficient wettability to the Al conductive layer (specifically, wettability of Ti≈TiAl>TiAlN≈TiN>>TaN). Accordingly, the TiAlN multi-function wetting/blocking layer provides improved blocking ability and wettability, leading to reduced leakage current and improved device performance, as compared to gate stacks including conventional TaN blocking layer/Ti wetting layer. Different embodiments may have different advantages, and that no particular advantage is necessarily required of any embodiment.

The present disclosure provides for many different embodiments. In an example, an integrated circuit device includes a semiconductor substrate and a gate stack disposed over the semiconductor substrate. The gate stack includes a gate dielectric layer disposed over the semiconductor substrate; a work function layer disposed over the gate dielectric layer; a multi-function wetting/blocking layer disposed over the work function layer, wherein the multi-function wetting/blocking layer is a titanium aluminum nitride layer; and a conductive layer disposed over the multi-function wetting/blocking layer. The gate dielectric layer may include a high-k dielectric layer. The gate dielectric layer may include an interfacial dielectric layer disposed between the high-k dielectric layer and the semiconductor substrate. The titanium aluminum nitride layer has a nitrogen atomic concentration that prevents metal impurities from penetrating the gate dielectric layer. For example, the nitrogen atomic concentration is about 10% to about 50%. The conductive layer may be an aluminum layer, and a the titanium aluminum nitride layer may have a ratio of titanium, aluminum, and nitrogen that optimizes wettability between the titanium aluminum nitride layer and the aluminum layer. For example, the titanium aluminum nitride layer may have a Ti:Al ratio of about 1:1 to about 1:3.

In another example, an integrated circuit device includes a gate stack disposed over a semiconductor substrate that includes a high-k dielectric layer disposed over the semiconductor substrate; a work function layer disposed directly on the high-k dielectric layer; a titanium aluminum nitride layer disposed directly on the work function layer; and an aluminum layer disposed directly on the titanium aluminum nitride layer. The gate stack may further include an interfacial dielectric layer disposed between the high-k dielectric layer and the semiconductor substrate. The titanium aluminum nitride layer may have a nitrogen atomic concentration of about 10% to about 50%. The titanium aluminum nitride layer may have a Ti:Al ratio of about 1:1 to about 1:3. The integrated circuit device may further include spacers disposed along sidewalls of the gate stack. The gate stack may interpose a source feature and a drain feature disposed in the semiconductor substrate.

In yet another example, the method includes forming a gate structure over a semiconductor substrate, wherein the gate structure has a gate stack that includes a high-k dielectric layer disposed over the semiconductor substrate and a dummy gate disposed over the high-k dielectric layer; removing the dummy gate from the gate structure, thereby forming an opening; and forming a work function layer over the high-k dielectric layer, a multi-function wetting/blocking layer over the work function layer, and a conductive layer over the multi-function wetting/blocking layer, wherein the work function layer, the multi-function wetting/blocking layer, and the conductive layer fill the opening, and further wherein the multi-function wetting/blocking layer is a titanium aluminum nitride layer. The method may further include forming a source feature and a drain feature in the semiconductor substrate, wherein the gate structure interposes the source feature and the drain feature. A physical vapor deposition process may be used to form the multi-function wetting/blocking layer over the work function layer. The physical vapor deposition process may be tuned such that the titanium aluminum nitride layer has a nitrogen atomic concentration of about 10% to about 50%. The physical vapor deposition process may be tuned such that the titanium aluminum nitride layer has a Ti:Al ratio of about 1:1 to about 1:3. The physical vapor deposition process may implement a chamber pressure of about 20 mTorr to about 40 mTorr.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit device comprising:
a semiconductor substrate; and
a gate stack disposed over the semiconductor substrate, wherein the gate stack includes:
a gate dielectric layer disposed over the semiconductor substrate,
a work function layer disposed over the gate dielectric layer,
a multi-function wetting/blocking layer disposed over the work function layer, wherein the multi-function wetting/blocking layer is a titanium aluminum nitride layer, and
a conductive layer disposed over the multi-function wetting/blocking layer.

2. The integrated circuit device of claim 1 wherein the gate dielectric layer includes a high-k dielectric layer.

3. The integrated circuit device of claim 2 wherein the gate dielectric layer includes an interfacial dielectric layer disposed between the high-k dielectric layer and the semiconductor substrate.

4. The integrated circuit device of claim 1 wherein the titanium aluminum nitride layer has a nitrogen atomic concentration that prevents metal impurities from penetrating the gate dielectric layer.

5. The integrated circuit device of claim 4 wherein the nitrogen atomic concentration is about 10% to about 50%.

6. The integrated circuit device of claim 1 wherein the conductive layer is an aluminum layer.

7. The integrated circuit device of claim 6 wherein the titanium aluminum nitride layer has a ratio of titanium, aluminum, and nitrogen that optimizes wettability between the titanium aluminum nitride layer and the aluminum layer.

8. The integrated circuit device of claim 7 wherein the titanium aluminum nitride layer has a Ti:Al ratio of about 1:1 to about 1:3.

9. An integrated circuit device comprising a gate stack disposed over a semiconductor substrate, wherein the gate stack includes:
a high-k dielectric layer disposed over the semiconductor substrate;
a work function layer disposed directly on the high-k dielectric layer;
a titanium aluminum nitride layer disposed directly on the work function layer; and
an aluminum layer disposed directly on the titanium aluminum nitride layer.

10. The integrated circuit device of claim 9 wherein the titanium aluminum nitride layer has a nitrogen atomic concentration of about 10% to about 50%.

11. The integrated circuit device of claim 9 wherein the titanium aluminum nitride layer has a Ti:Al ratio of about 1:1 to about 1:3.

12. The integrated circuit device of claim 9 further including spacers disposed along sidewalls of the gate stack.

13. The integrated circuit device of claim 9 wherein the gate stack interposes a source feature and a drain feature disposed in the semiconductor substrate.

14. The integrated circuit device of claim 9 wherein the gate stack further includes an interfacial dielectric layer disposed between the high-k dielectric layer and the semiconductor substrate.

15. A method comprising:
forming a gate structure over a semiconductor substrate, wherein the gate structure has a gate stack that includes a high-k dielectric layer disposed over the semiconductor substrate and a dummy gate disposed over the high-k dielectric layer;
removing the dummy gate from the gate structure, thereby forming an opening; and
forming a work function layer over the high-k dielectric layer, a multi-function wetting/blocking layer over the work function layer, and a conductive layer over the multi-function wetting/blocking layer, wherein the work function layer, the multi-function wetting/blocking layer, and the conductive layer fill the opening, and further wherein the multi-function wetting/blocking layer is a titanium aluminum nitride layer.

16. The method of claim 15 wherein the forming the multi-function wetting/blocking layer over the work function layer includes performing a physical vapor deposition process.

17. The method of claim 16 wherein the performing the physical vapor deposition process includes tuning the physical vapor deposition process such that the titanium aluminum nitride layer has a nitrogen atomic concentration of about 10% to about 50%.

18. The method of claim 16 wherein the performing the physical vapor deposition process includes tuning the physical vapor deposition process such that the titanium aluminum nitride layer has a Ti:Al ratio of about 1:1 to about 1:3.

19. The method of claim 16 wherein the performing the physical vapor deposition process includes performing the physical vapor deposition process at a chamber pressure of about 20 mTorr to about 40 mTorr.

20. The method of claim 15 further including forming a source feature and a drain feature in the semiconductor substrate, wherein the gate structure interposes the source feature and the drain feature.
